(19) United States
(12) Patent Application Publication
(10) Pub. No.: US 2021/0358767 A1
(43) Pub. Date: Nov. 18, 2021

(54) MULTILAYER WIRING FORMING METHOD AND RECORDING MEDIUM

(71) Applicant: Tokyo Electron Limited, Tokyo (JP)

(72) Inventors: Takashi Tanaka, Kikuchi-gun (JP); Mitsuaki Iwashita, Kikuchi-gun (JP)

(21) Appl. No.: 16/938,047

(22) PCT Filed: Jan. 23, 2019
(86) PCT No.: PCT/JP2019/002070

§ 371 Date: Jul. 24, 2020

(30) Foreign Application Priority Data
Feb. 1, 2018 (JP) 2018-016059

(51) Int. Cl. H01L 21/48; H01L 21/768; C23C 18/16

(52) U.S. Cl. CPC H01L 21/486; C23C 18/1657; C23C 18/1642; H01L 21/76874

(57) ABSTRACT

A multilayer wiring forming method includes forming, in a via 70 formed at a preset position in an insulating film 60 provided on a wiring 50 of a substrate, the via 70 being extended to the wiring 70, a monomolecular film 80 on a bottom surface 73 at which the wiring 50 is exposed; forming a barrier film 81 on a side surface 72 of the via 70; removing the monomolecular film 80; and forming an electroless plating film 82 from the bottom surface 73 of the via 70 by using the wiring 50 exposed at the bottom surface 73 of the via 70 as the catalyst.

### TECHNICAL FIELD

The various aspects and embodiments described herein pertain generally to a multilayer wiring forming method and a recording medium therefor.

### BACKGROUND

Conventionally, as a way to form a multilayer wiring in a semiconductor wafer (hereinafter, referred to as “wafer”) as a substrate, there is known a method in which a barrier layer and a seed layer are formed on an inner surface of a via which is formed in an insulating film provided on the wiring, and the inside of the via is filled by performing an electrolytic plating processing (see, for example, Patent Document 1).

### PRIOR ART DOCUMENT

Patent Document 1: Japanese Patent Laid-open Publication No. 2013-194306

### DISCLOSURE OF THE INVENTION

### Problems to be Solved by the Invention

In the conventional multilayer wiring forming method, however, if an aspect ratio of the via is high, a ratio of the barrier layer and the seed layer to the via is high, and the via has a narrow and long shape. Thus, it is difficult to fill a bottom portion of the via effectively through the electrolytic plating processing. As a result, a defect such as a void or a seam may be generated in the vicinity of the bottom portion of the via, which raises a likelihood that reliability of a semiconductor device may be deteriorated.

In view of the foregoing, exemplary embodiments provide a multilayer wiring forming method capable of forming a metal wiring successfully in the vicinity of the bottom portion of the via having the high aspect ratio, and also provide a recording medium therefor.

### Means for Solving the Problems

In one exemplary embodiment, a multilayer wiring forming method includes forming, in a via formed at a preset position in an insulating film provided on a wiring of a substrate, the via being extended to the wiring, a monomolecular film on a bottom surface of the via at which the wiring is exposed; forming a barrier film on a side surface of the via; removing the monomolecular film; and forming an electroless plating film from the bottom surface of the via by using the wiring exposed at the bottom surface of the via as a catalyst.

### Means For Solving The Problems

According to the exemplary embodiments, it is possible to form the metal wiring near the bottom portion of the via having a high aspect ratio.

### BRIEF DESCRIPTION OF THE DRAWINGS

FIG. 1 is a schematic diagram illustrating a schematic configuration of a multilayer wiring forming system according to an exemplary embodiment.

FIG. 2 is a cross sectional view illustrating a configuration of an electroless plating unit according to the exemplary embodiment.

FIG. 3 is a cross sectional view illustrating a configuration of an electrolytic plating unit according to the exemplary embodiment.

FIG. 4A is a first schematic diagram for describing a multilayer wiring forming processing according to the exemplary embodiment.

FIG. 4B is a second schematic diagram for describing the multilayer wiring forming processing according to the exemplary embodiment.

FIG. 4C is a third schematic diagram for describing the multilayer wiring forming processing according to the exemplary embodiment.

FIG. 4D is a fourth schematic diagram for describing the multilayer wiring forming processing according to the exemplary embodiment.

FIG. 4E is a fifth schematic diagram for describing the multilayer wiring forming processing according to the exemplary embodiment.

FIG. 4F is a sixth schematic diagram for describing the multilayer wiring forming processing according to the exemplary embodiment.

FIG. 4G is a seventh schematic diagram for describing the multilayer wiring forming processing according to the exemplary embodiment.

FIG. 5 is a flowchart illustrating a processing sequence of the multilayer wiring forming processing according to the exemplary embodiment.

### DETAILED DESCRIPTION

Hereinafter, exemplary embodiments of a multilayer wiring forming method and a recording medium therefor according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios

<Outline of Multilayer Wiring Forming System>.

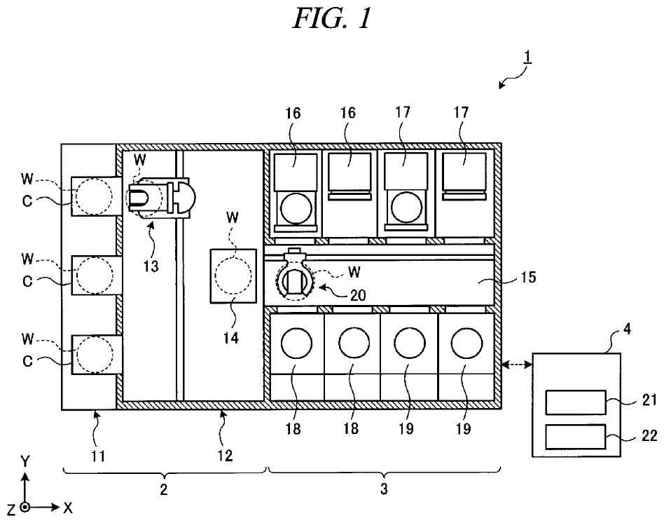

First, referring to FIG. 1, a schematic configuration of a multilayer wiring forming system 1 according to an exemplary embodiment will be explained. FIG. 1 is a diagram illustrating the schematic configuration of the multilayer wiring forming system according to the exemplary embodiment. In the following, in order to clarify positional relationships, the X-axis, Y-axis and Z-axis which are orthogonal to each other will be defined. The positive Z-axis direction will be regarded as a vertically upward direction.

As depicted in FIG. 1, the multilayer wiring forming system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, carriers C each accommodating therein semiconductor wafers W (hereinafter, referred to as “wafers W”) horizontally are placed.

The transfer section 12 is provided adjacent to the carrier placing section 11, and provided with a substrate transfer device 13 and a delivery unit 14. The substrate transfer device 13 is provided with a wafer holding mechanism configured to hold the wafer W. Further, the substrate transfer device 13 is movable horizontally and vertically and pivotable around a vertical axis, and transfers the wafer W between the carriers C and the delivery unit 14 by using the wafer holding mechanism.

The processing station 3 is provided adjacent to the transfer section 12. The processing station 3 is provided with a transfer section 15, a plurality of monomolecular film forming units 16, a plurality of film forming units 17, a plurality of electroless plating units 18, and a plurality of electrolytic plating units 19.

The plurality of monomolecular film forming units 16, the plurality of film forming units 17, the plurality of electroless plating units 18 and the plurality of electrolytic plating units 19 are arranged side by side at both sides of the transfer section 15. Further, the layout and the number of the monomolecular film forming units 16, the film forming units 17, the electroless plating units 18 and the electrolytic plating units 19 shown in FIG. 1 are just an example and are not limited thereto.

The transfer section 15 is provided with a substrate transfer device 20 therein. The substrate transfer device 20 is provided with a wafer holding mechanism configured to hold the wafer W. Further, the substrate transfer device 20 is movable horizontally and vertically and pivotable around a vertical axis. The substrate transfer device 20 transfers the wafer W between the delivery unit 14, the monomolecular film forming units 16, the film forming units 17, the electroless plating units 18 and the electrolytic plating units 19 by using the wafer holding mechanism.

The monomolecular film forming unit 16 is configured to perform a preset monomolecular film forming processing on the wafer W transferred by the substrate transfer device 20. The monomolecular film forming unit 16 is, by way of non-limiting example, a vacuum chamber having a heater.

The film forming unit 17 is configured to perform a preset film forming processing on the wafer W transferred by the substrate transfer device 20. The film forming unit 17 is a dry-process apparatus such as, but not limited to, a PVD (Physical Vapor Deposition) apparatus or a CVD (Chemical Vapor Deposition) apparatus.

The electroless plating unit 18 is configured to perform a preset electroless plating processing on the wafer W transferred by the substrate transfer device 20. A configuration example of this electroless plating unit 18 will be elaborated later.

The electrolytic plating unit 19 is configured to perform a preset electrolytic plating processing on the wafer W transferred by the substrate transfer device 20. A configuration example of this electrolytic plating unit 19 will be described later.

Further, the substrate processing system 1 is equipped with a control device 4. The control device 4 is, for example, a computer, and includes a controller 21 and a storage 22.

The controller 21 includes various circuits and a microcomputer having a CPU (Central Processing Unit), a ROM (Read Only Memory), a RAM (Random Access Memory), an input/output port, and so forth.

The CPU of the microcomputer carries out controls over the transfer sections 12 and 15, the monomolecular film forming units 16, the film forming units 17, the electroless plating units 18, the electrolytic plating units 19, and so forth by reading out and executing programs stored in ROM.

Further, the programs may be recorded in a computer-readable recording medium and may be installed to the storage 22 of the control device 4 from this recording medium. The computer-readable recording medium may be, by way of non-limiting example, a hard disk (HD), a flexible disk (FD), a compact disk (CD), a magnet optical disk (MO), a memory card, or the like.

The storage 22 may be implemented by, for example, a semiconductor memory device such as a RAM or a flash memory, or a storage device such as a hard disk or an optical disk.

In the multilayer wiring forming system 1 configured as described above, the substrate transfer device 13 of the carry-in/out station 2 first takes out the wafer W from the carrier C placed in the carrier placing section 11, and then, places the taken wafer W on the delivery unit 14. The wafer W placed on the delivery unit 14 is taken out from the delivery unit 14 by the substrate transfer device 20 of the processing station 3, and then, carried into the molecular film forming unit 16.

The wafer W carried into the monomolecular film forming unit 16 is subjected to the preset monomolecular film forming processing by the monomolecular film forming unit 16, and is then taken out of the monomolecular film forming unit 16 to be carried into the film forming unit 17 by the substrate transfer device 20.

The wafer W carried into the film forming unit 17 is subjected to a preset barrier film forming processing by the film forming unit 17, and is then taken out of the film forming unit 17 and carried into the electroless plating unit 18 by the substrate transfer device 20.

The wafer W carried into the electroless plating unit 18 is subjected to a preset monomolecular film removing processing and the preset electroless plating processing by the electroless plating unit 18, and is then taken out of the electroless plating unit 18 and carried into the film forming unit 17 by the substrate transfer device 20.

The wafer W carried into the film forming unit 17 is subjected to a preset seed film forming processing by the film forming unit 17, and is then taken out of the film forming unit 17 to be carried into the electrolytic plating unit 19 by the substrate transfer device 20.

The wafer W carried into the electrolytic plating unit 19 is subject ted to the preset electrolytic plating processing by the electrolytic plating unit 19, and is then taken out of the electrolytic plating unit 19 to be placed in the delivery unit 14 by the substrate transfer device 20. Then, the wafer, on which the processings are completely performed, is returned back into the carrier C of the carrier placing section 11 by the substrate transfer device 13.

<Outline of Electroless Plating Unit>

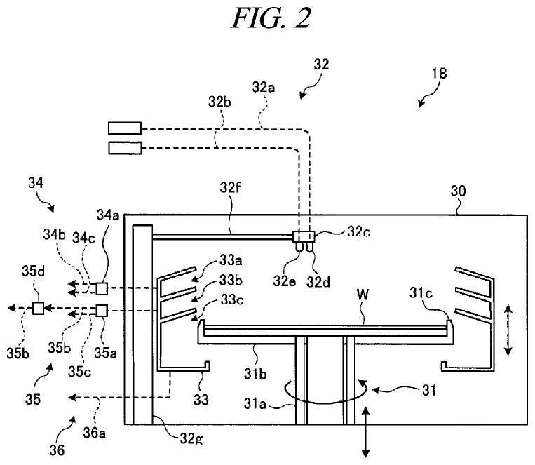

Now, referring to FIG. 2, a schematic configuration of the electroless plating unit 18 will be explained. FIG. 2 is a cross sectional view illustrating the configuration of the electroless plating unit 18 according to the exemplary embodiment. By way of example, the electroless plating unit 18 is configured as a single wafer processing unit configured to process the wafers W one by one.

The electroless plating unit 18 is equipped with, as depicted in FIG. 2, a housing 30, a substrate holding/rotating device 31, a processing liquid supply device 32, a cup 33, and liquid draining device 34 to 36.

The substrate holding/rotating device 31 is configured to hold and rotate the wafer W within the housing 30. The substrate holding/rotating device 31 includes a rotary shaft 31a, a turntable 31b, a wafer chuck 31c and a non-illustrated rotating mechanism.

The rotary shaft 31a is of a hollow cylindrical shape and is vertically extended within the housing 30. The turntable 31b is provided to an upper end of the rotary shaft 31a. The wafer chuck 31c is provided at an edge portion of a top surface of the turntable 31b to support the wafer W.

The substrate holding/rotating device 31 is controlled by the controller 21 of the control device 4, and the rotary shaft 31a is rotated by the rotating mechanism. Accordingly, the wafer W supported by the wafer chuck 31c can be rotated.

The processing liquid supply device 32 is configured to supply preset processing liquids onto a surface of the wafer W held by the substrate holding/rotating device 31. The processing liquid supply device 32 includes a first processing liquid supply device 32a configured to supply a first processing liquid onto the surface of the wafer W; and a second processing liquid supply device 32b configured to supply a second processing liquid onto the surface of the wafer W.

The first processing liquid is, by way of non-limiting example, TMAH (Tetramethyl Ammonium Hydroxide). The second processing liquid is, for example, an electroless plating liquid.

The processing liquid supply device 32 is equipped with a nozzle head 32c, and nozzles 32d and 32e are provided at this nozzle head 32c. The nozzles 32d and 32e correspond to the first processing liquid supply device 32a and the second processing liquid supply device 32b, respectively.

The nozzle head 32c is fastened to a leading end of an arm 32f. This arm 32f is configured to be movable up and down, and is rotatably fixed to a supporting shaft 32g which is rotated by a non-illustrated rotating mechanism.

With this configuration, the processing liquid supply device 32 is capable of discharging the preset processing liquids to a required position on the surface of the wafer W from a required height through the nozzles 32d and 32e.

The cup 33 is configured to receive the processing liquid scattered from the wafer W. The cup 33 has three drain openings 33a to 33c, and is configured to be movable up and down by a non-illustrated elevating mechanism. The three drain openings 33a to 33c are connected to the liquid draining devices 34 to 36, respectively.

The liquid draining devices 34 to 36 drain the processing liquids collected into the drain openings 33a to 33c, respectively. The liquid draining device 34 is equipped with a recovery path 34b and a waste path 34c which are switched by a path switching device 34a. The recovery path 34b is a path for collecting and reusing, for example, the first processing liquid, and the waste path 34c is a path for draining out the first processing liquid.

The liquid draining device 35 is equipped with a recovery path 35b and a waste path 35c which are switched by a path switching device 35a. The recovery path 35b is a path for collecting and reusing, for example, the second processing liquid, and the waste path 35c is a path for draining out the second processing liquid.

Further, if the second processing liquid is the electroless plating liquid, a cooling buffer 35d is provided at an outlet side of the recovery path 35b to cool the electroless plating liquid. Further, the liquid draining device 36 is only provided with a waste path 36a.

In the present exemplary embodiment, though the processing liquids are supplied onto the wafer W from the nozzles 32d and 32e, a device configured to supply the processing liquids onto the wafer W is not limited to the nozzles, and various other kinds of devices may be used.

<Outline of Electrolytic Plating Unit>

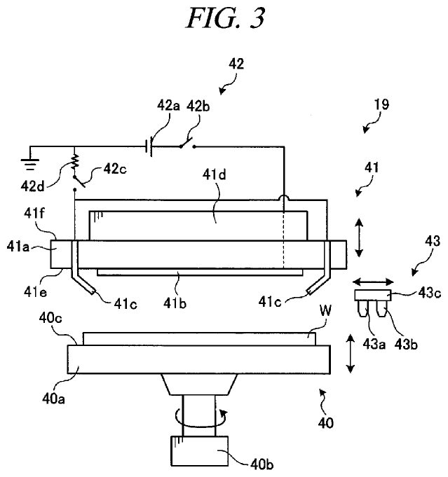

Now, referring to FIG. 3, a schematic configuration of the electrolytic plating unit 19 will be explained. FIG. 3 is a cross sectional view illustrating the configuration of the electrolytic plating unit 19 according to the exemplary embodiment. For example, the electrolytic plating unit 19 is configured as a single-wafer processing unit configured to process the wafers W one by one.

The electrolytic plating unit 19 is equipped with a substrate holder 40, an electrolytic processing device 41, a voltage applying device 42, and a processing liquid supply device 43.

The substrate holder 40 serves to hold the wafer W. The substrate holder 40 includes a wafer chuck 40a and a driving device 40b.

The wafer chuck 40a is, by way of non-limiting example, a spin chuck configured to hold and rotate the wafer W. The wafer chuck 40a is of a substantially circular plate shape, and has a top surface 40c extending in a horizontal direction and having a diameter larger than that of the wafer W when viewed from the top. This top surface 40c is provided with a suction opening (not shown) for attracting the wafer W, and the wafer W can be held on the top surface 40c of the wafer chuck 40a by suctioning through the suction opening.

The substrate holder 40 is equipped with the driving device 40b, having a motor or the like, configured to rotate the wafer chuck 40a at a preset speed. Further, the driving device 40b is equipped with an elevational driving unit (not shown) such as a cylinder and capable of moving the wafer chuck 40a in a vertical direction.

The electrolytic processing device 41 is disposed above the substrate holder 40, facing the top surface 40c of the wafer chuck 40a. The electrolytic processing device 41 includes a base 41a, a direct electrode 41b, contact terminals 41c and a moving device 41d.

The base 41a is made of an insulating material. The base 41a is of a substantially circular plate shape, and has a bottom surface 41e having a diameter larger than that of the wafer W when viewed from the top and a top surface 41f arranged at an opposite side from the bottom surface 41e.

The direct electrode 41b is made of a conductive material and provided on the bottom surface 41e of the base 41a. The direct electrode 41b is disposed to face the wafer W held by the substrate holder 40, substantially in parallel therewith. When the electrolytic plating processing is performed, the direct electrode 41b comes into direct contact with the electrolytic plating liquid accumulated on the wafer W.

The contact terminals 41c are protruded from the bottom surface 41e at a peripheral portion of the base 41a. Each contact terminal 41c is made of a conductor having elasticity, and is curved toward a center of the bottom surface 41e.

Two or more, for example, thirty two (32) contact terminals 41c are provided at the base 41a. When viewed from the top, the contact terminals 41c may be arranged on a concentric circle of the base 41a at a regular distance therebetween. Leading ends of all the contact terminals 41c are arranged such that an imaginary plane formed by these leading ends is substantially in parallel with the surface of the wafer W held by the substrate holder 40.

These contact terminals 41c come into contact with a peripheral portion of the wafer W when the electrolytic plating processing is performed, and are configured to apply a voltage to the wafer W. Further, the number and the layout of the contact terminals 41c are not limited to the example of the above-described exemplary embodiment.

The direct electrode 41b and the contact terminals 41c are connected to the voltage applying device 42, and are capable of applying a preset voltage to the electrolytic plating liquid and the wafer W that they come into contact with, respectively.

The moving device 41d is provided on the top surface 41f of the base 41a. The moving device 41d has an elevational driving unit (not shown) such as, but not limited to, a cylinder. The moving device 41d is capable of moving the entire electrolytic processing device 41 in the vertical direction by using the elevational driving unit.

The voltage applying device 42 includes a DC power supply 42a, switches 42b and 42c and a load resistor 42d, and is connected with the direct electrode 41b and the contact terminals 41c of the electrolytic processing device 41. To elaborate, an anode of the DC power supply 42a is connected to the direct electrode 41b via the switch 42b, and a cathode of the DC power supply 42a is connected to the multiple contact terminals 41c via the switch 42c and the load resistor 42d. Further, the cathode of the DC power supply 42a is grounded.

By turning the switches 42b and 42c into an on state or an off state at the same time, the voltage applying device 42 is capable of applying the voltage to the direct electrode 41b and the contact terminals 41c in a pulse shape.

The processing liquid supply device 43 is provided between the substrate holder 40 and the electrolytic processing device 41. This processing liquid supply device 43 is equipped with nozzles 43a and 43b and a moving device 43c. The nozzle 43a supplies a cleaning liquid such as DHF (Diluted HydroFluoric acid) onto the wafer W. The nozzle 43b supplies the electrolytic plating liquid onto the wafer W.

The moving device 43c is configured to move the nozzles 43a and 43b in the horizontal direction and the vertical direction. That is, the nozzles 43a and 43b are configured to be advanced to or retreated from the substrate holder 40.

Further, the nozzle 43a communicates with a non-illustrated cleaning liquid source which stores the cleaning liquid therein, and the cleaning liquid can be supplied to the nozzle 43a from this cleaning liquid source. The nozzle 43b communicates with a non-illustrated plating liquid source which stores the electrolytic plating liquid therein, and the electrolytic plating liquid can be supplied to the nozzle 43b from this plating liquid source.

Furthermore, though the processing liquids are supplied onto the wafer W from the nozzles 43a and 43b in the exemplary embodiment, a device configured to supply the processing liquids onto the wafer W is not limited to the nozzles, and various other kinds of devices may be used.

<Details of Multilayer Wiring Forming Processing>

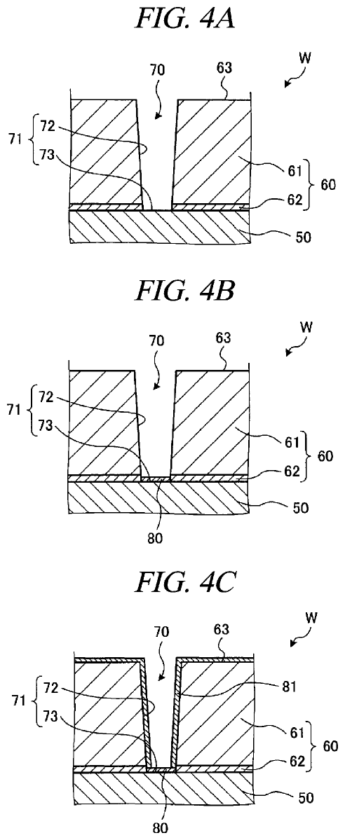

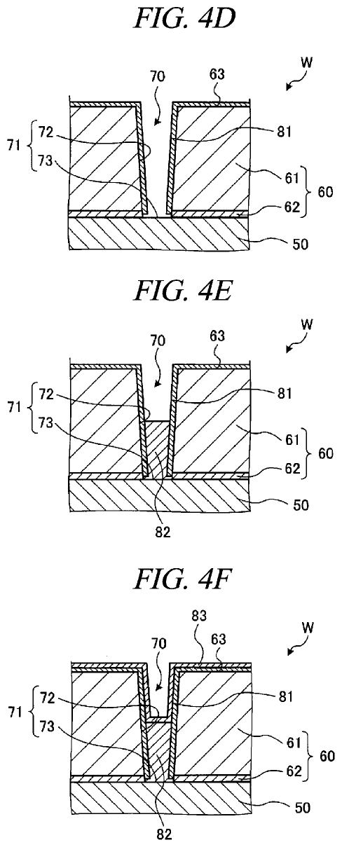

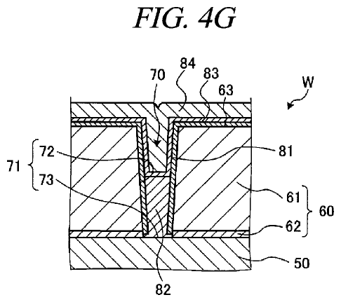

Now, referring to FIG. 4A to FIG. 4G, details of a multilayer wiring forming processing according to the exemplary embodiment will be explained. FIG. 4A to FIG. 4G are first to seventh schematic diagrams for describing the multilayer wiring forming processing according to the exemplary embodiment.

Further, the wafer W shown in FIG. 4A to FIG. 4G is already provided with non-illustrated devices formed thereon. Various kinds of processings for filling a via 70, which is formed in an insulating film 60 formed on a wiring 50, in a wiring forming process after the formation of these devices (a so-called BEOL (Back End of Line)) will be elaborated below.

As depicted in FIG. 4A, the wiring 50 made of a metal is formed on the wafer W, and the insulating film 60 is provided on the wiring 50. The wiring 50 is formed of a conductive material including, by way of non-limiting example, Cu, Co, Ni or Ru.

The insulating film 60 has, for example, an oxide film 61 and a nitride film 62. The nitride film 62 is formed on the wiring 50 to have a preset thickness, and the oxide film 61 is formed on this nitride film 62 to have a predetermined thickness. In case that the wiring 50 is made up of an element such as Cu which is diffused within the oxide film 61, the nitride film 62 serves as a barrier film which suppresses this element from being diffused within the oxide film 61.

Further, the wafer W has the via 70 formed at a preset position in the insulating film 60. This via 70 is formed to extend from a top surface 63 of the insulating film 60 to the wiring 50. The via 70 has an inner surface 71, and the inner surface 71 includes a side surface 72 and a bottom surface 73 at which the wiring 50 is exposed.

Here, as a way to form the via 70 in the insulating film 60 of the wafer W, a commonly known method in the art may be appropriately employed. To be specific, a general-purpose technique using a fluorine-based gas, a chlorine-based gas, or the like may be utilized as a dry etching technique, for example.

Particularly, in order to form the via 70 having a high aspect ratio (a ratio of a depth to a diameter), an ICP-RIE (Inductively Coupled Plasma Reactive Ion Etching) technique capable of performing a high-speed deep etching may be adopted.

By way of example, a so-called Bosch process in which an etching process using sulfur hexafluoride (SF₆) and a protection process using a Teflon (registered trademark)-based gas such as C₄F₈ are repeatedly performed may be appropriately performed.

As illustrated in FIG. 4A, the wafer W having the via 70 in the insulating film 60 on the wiring 50 is carried into the aforementioned monomolecular film forming unit 16 to be subjected to the preset monomolecular film forming processing. In this monomolecular film forming processing, a coupling agent such as a silane coupling agent or a titanium coupling agent is vaporized to be adsorbed.

Accordingly, as shown in FIG. 4B, a monomolecular film 80 is formed on the wiring 50 exposed at the bottom surface 73 of the via 70. Further, since this monomolecular film 80 is formed by using the coupling agent configured to be adsorbed only to a metal, the monomolecular film 80 is formed only on the wiring 50 and is not formed on the surface of the insulating film 60.

That is, according to the exemplary embodiment, by forming the monomolecular film 80 with the coupling agent, it is possible to form the monomolecular film 80 selectively on the bottom surface 73 of the via 70.

Furthermore, though the exemplary embodiment has been described for the example where the monomolecular film 80 is formed by adsorbing the coupling agent within the vacuum chamber, a method of forming the monomolecular film 80 is not limited to this example. By way of example, a processing liquid in which the coupling agent is dissolved may be discharged on the wafer W, and the monomolecular film 80 may be formed by spinning the wafer W on which the processing liquid is discharged.

Then, the wafer W having the monomolecular film 80 formed thereon is carried into the aforementioned film forming unit 17 to be subjected to the preset barrier film forming processing. This barrier film forming processing is performed by using a general-purpose technique such as a PVD method or a CVD method.

As a result, as shown in FIG. 4C, a barrier film 81 formed of a Co—W—B alloy or the like is formed on the side surface 72 and the top surface 63 of the insulating film 60. Here, since the barrier film 81 is difficult to form on a surface of the monomolecular film 80, the barrier film 81 is not formed on the bottom surface 73 of the via 70.

Further, though the exemplary embodiment has been described for the example where the barrier film 81 is formed of the Co—W—B alloy, the barrier film 81 is not limited to the Co—W—B alloy and only needs to be made of a material capable of suppressing an element included in an electroless plating film 82 (see FIG. 4E) or an electrolytic plating film 84 (see FIG. 4G) to be described later from being diffused into the oxide film 61.

Furthermore, the exemplary embodiment has been described for the example where the barrier film 81 is formed by performing the dry process such as the PVD method or the CVD method. However, the barrier film 81 may be formed by performing a wet process such as, but not limited to, an electroless plating processing, without being limited to the dry process.

Thereafter, the wafer W having the barrier film 81 formed thereon is carried into the aforementioned electroless plating unit 18 to be subjected to the preset monomolecular film removing processing. In this monomolecular film removing processing, for example, the TMAH as the first processing liquid is discharged onto the wafer W by controlling the first processing liquid supply device 32a of the electroless plating unit 18.

As a result, as depicted in FIG. 4D, the monomolecular film 80 formed on the bottom surface 73 of the via 70 is dissolved to be removed. Further, in the present exemplary embodiment, though the monomolecular film 80 is removed by the TMAH, the processing liquid for use in removing the monomolecular film 80 may not be limited thereto. Further, in the monomolecular film removing processing, the monomolecular film 80 may be removed by being decomposed with high heat, or may be removed by being etched by plasma.

Subsequently, the preset electroless plating processing is performed on the wafer W from which the monomolecular film 80 is removed. In this electroless plating processing, for example, the electroless plating liquid as the second processing liquid is discharged onto the wafer W by controlling the second processing liquid supply device 32b of the electroless plating unit 18.

Accordingly, as depicted in FIG. 4E, the electroless plating film 82 is formed from the bottom surface 73 of the via 70 in a bottom-up manner by using the wiring 50 exposed at the bottom surface 73 of the via 70 as a catalyst. Further, in the present exemplary embodiment, the electroless plating film 82 is formed in a lower portion of the via 70 including the vicinity of a bottom portion thereof.

As stated above, by forming the electroless plating film 82 from the bottom surface 73 in the bottom-up manner while using the wiring 50 exposed at the bottom surface 73 as the catalyst, it is possible to form a metal wiring without having a void or a seam near the bottom portion of the via 70 having a high aspect ratio and in which it is difficult to form the metal wiring.

Moreover, in the exemplary embodiment, since the electroless plating film 82 is formed by using the wiring 50 as the catalyst, the wiring 50 and the electroless plating film 82 can be in direct contact with each other without having a barrier film, a seed film, or the like therebetween. Accordingly, electric resistance of the metal wiring formed within the via 70 can be reduced.

In the exemplary embodiment, the electroless plating film 82 needs to contain Cu, Co, Ni or Ru. Accordingly, the electroless plating film 82 can be formed efficiently from the bottom surface 73 of the via 70 by using the wiring 50 containing Cu, Co, Ni or Ru as the catalyst.

Thereafter, the wafer W having the electroless plating film 82 formed thereon is carried into the aforementioned film forming unit 17 to be subjected to the preset seed film forming processing. This seed film forming processing is performed by using a general-purpose technique such as a PVD method, a CVD method, or the like.

As a result, as depicted in FIG. 4F, a seed film 83 is formed on the inner surface 71 of the via 70 and the top surface 63 of the insulating film 60. The seed film 83 is made of a material serving as a catalyst when the electrolytic plating film 84 (see FIG. 4G) to be described later is formed. By way of example, when the electrolytic plating film 84 is made of Cu or a Cu alloy, the seed film 83 needs to contain Cu, whereas when the electrolytic plating film 84 is made of Co or a Co alloy, the seed film 83 needs to contain Co.

Subsequently, the wafer W having the seed film 83 formed thereon is carried into the aforementioned electrolytic plating unit 19 to be first subjected to a preset cleaning processing. In this cleaning processing, for example, the DHF as the cleaning liquid is discharged onto the wafer W from the nozzle 43a of the processing liquid supply device 43.

Accordingly, a natural oxide film, a deposit or the like formed on a surface of the seed film 83 is removed, so that the surface of the seed film 83 can be maintained clean.

Thereafter, the preset electrolytic plating processing is performed on the wafer W after being subjected to the cleaning processing. In this electrolytic plating processing, for example, the electrolytic plating liquid is first accumulated on the wafer W by using the nozzle 43b of the processing liquid supply device 43 of the electrolytic plating unit 19 shown in FIG. 3.

Then, the entire electrolytic processing device 41 is made to approach the wafer W held by the substrate holder 40 by the moving device 41d, thus allowing the leading ends of the contact terminals 41c to come into contact with the peripheral portion of the wafer W. At this time, the direct electrode 41b comes into direct contact with the electrolytic plating liquid accumulated on the wafer W.

Afterwards, by turning the switches 42b and 42c of the voltage applying device 42 into the on state from the off state simultaneously, the voltage is applied to the wafer W and the electrolytic plating liquid with the direct electrode 41b as the anode and the wafer W as the cathode, so that an electric current flows between the direct electrode 41b and the wafer W.

As a result, metal ions are reduced on the surface of the wafer W, so that the electrolytic plating film 84 is precipitated on the surface of the seed film 83 with the seed film 83 as a catalyst, and the inside of the via 70 is filled with the electrolytic plating film 84. By way of example, by using the electrolytic plating liquid containing Cu, it is possible to form the electrolytic plating film 84 containing Cu, or by using the electrolytic plating liquid containing Co, it is possible to form the electrolytic plating film 84 containing Co.

According to the exemplary embodiment, through the various processings described so far, the inside of the via 70 having the high aspect ratio can be filled with the metal wiring effectively.

<Details of Multilayer Wiring Forming Processing>

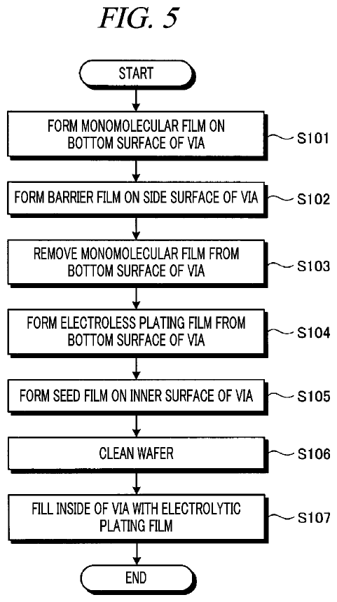

Now, referring to FIG. 5, details of the multilayer wiring forming processing according to the exemplary embodiment will be discussed. FIG. 5 is a flowchart illustrating a processing sequence of the multilayer wiring forming processing according to the exemplary embodiment.

Further, the multilayer wiring forming processing shown in FIG. 5 is performed as the controller 21 reads out the programs installed to the storage 2 from the recording medium according to the exemplary embodiment and controls the transfer section 15, the monomolecular film forming unit 16, the film forming unit 17, the electroless plating unit 18, the electrolytic plating unit 19, and so forth based on the read-out command.

First, the wafer W having the via 70 formed in the insulating film 60 on the wiring 50 is transferred into the monomolecular film forming unit 16 from the carrier C via the substrate transfer device 13, the delivery unit 14 and the substrate transfer device 20.

Then, the controller 21 controls the monomolecular film forming unit 16 to perform the monomolecular film forming processing on the wafer W, thus allowing the monomolecular film 80 to be formed on the bottom surface 73 of the via 70 (process S101). This monomolecular film forming processing is carried out by vaporizing and adsorbing the coupling agent such as the silane coupling agent or the titanium coupling agent within the vacuum chamber.

Subsequently, the controller 21 controls the substrate transfer device 20 to transfer the wafer W from the monomolecular film forming unit 16 into the film forming unit 17. Then, the controller 21 controls the film forming unit 17 to perform the barrier film forming processing on the wafer W, thus allowing the barrier film 81 to be formed on the side surface 72 of the via 70 and the top surface 63 of the insulating film 60 (process S102).

This barrier film forming processing is performed by forming the barrier film 81 of the Co—W—B alloy or the like on the wafer W by using the general-purpose technique such as, but not limited to, the PVD method or the CVD method.

Then, the controller 21 controls the substrate transfer device 20 to transfer the wafer W from the film forming unit 17 into the electroless plating unit 18. Thereafter, the controller 21 controls the electroless plating unit 18 to perform the monomolecular film removing processing on the wafer W, thus allowing the monomolecular film 80 to be removed from the bottom surface 73 of the via 70 (process S103).

This monomolecular film removing processing is carried out by discharging the TMAH onto the wafer W, for example, thus allowing the monomolecular film 80 formed on the bottom surface 73 of the via 70 to be dissolved by the TMAH.

Subsequently, the controller 21 controls the electroless plating unit 18 to perform the electroless plating processing on the wafer W, thus allowing the electroless plating film 82 to be formed from the bottom surface 73 of the via 70 (process S104).

This electroless plating processing is carried out by discharging the electroless plating liquid onto the wafer W, for example, thus allowing the electroless plating film 82 to be formed from the bottom surface 73 in the bottom-up manner by using the wiring 50 exposed at the bottom surface 73 as the catalyst.

Then, the controller 21 controls the substrate transfer device 20 to transfer the wafer W from the electroless plating unit 18 into the film forming unit 17. Then, the controller 21 controls the film forming unit 17 to perform the seed film forming processing on the wafer W, thus allowing the seed film 83 to be formed on the inner surface 71 of the via 70 and the top surface 63 of the insulating film 60 (process S105).

This seed film forming processing is carried out by forming the seed film 83 containing Cu or Co on the wafer W with the general-purpose technique such as, but not limited to, the PVD method or the CVD method.

Subsequently, the controller 21 controls the substrate transfer device 20 to transfer the wafer W from the film forming unit 17 into the electrolytic plating unit 19. Then, the controller 21 controls the electrolytic plating unit 19 to perform the cleaning processing on the wafer W, thus allowing the wafer W to be cleaned (process S106).

This cleaning processing is carried out by discharging the DHF onto the wafer W, for example, thus allowing the natural oxide film or the deposit formed on the surface of the seed film 83 to be removed by the DHF.

Next, the controller 21 controls the electrolytic plating unit 19 to perform the electrolytic plating processing on the wafer W, thus allowing the inside of the via 70 to be filled with the electrolytic plating film 84 (process S107).

In this electrolytic plating processing, for example, the electrolytic plating liquid is accumulated on the wafer W, and the leading ends of the contact terminals 41c are brought into contact with the peripheral portion of the wafer W and the direct electrode 41b is brought into direct contact with the electrolytic plating liquid.

The electrolytic plating processing is carried out by allowing the electric current to flow between the wafer W and the electrolytic plating liquid while applying the voltage to the wafer W and the electrolytic plating liquid with the direct electrode 41b as the anode and the wafer Was the cathode. If this electrolytic plating processing is finished, the multilayer wiring forming processing upon the wafer W is completed.

So far, the exemplary embodiment of the present disclosure has been described. However, the present disclosure is not limited to the above-described exemplary embodiment, and various changes and modifications may be made without departing from the technical scope of the present disclosure. By way of example, in the above-described exemplary embodiment, the electroless plating film 82 is formed near the bottom portion of the via 70, and then, the inside of the via 70 is filled with the electrolytic plating film 84 later. However, the inside of the via 70 may be filled with the electroless plating film 82 only.

Further, in the above-described exemplary embodiment, the electrolytic plating processing is performed by accumulating the electrolytic plating liquid on the wafer W. However, the electrolytic plating processing is not limited to this example. By way of example, the electrolytic plating processing may be performed by immersing the wafer W in an electrolytic tub in which the electrolytic plating liquid is stored.

Further, in the above-described exemplary embodiment, after the electroless plating film 82 or the electrolytic plating film 84 is formed, a preset sintering processing may be performed by using a hot plate or the like, thus reducing the electric resistance of the electroless plating film 82 or the electrolytic plating film 84.

The multilayer wiring forming method according to the exemplary embodiment is a forming method of a buried multilayer wiring. This multilayer wiring forming method includes forming, in the via 70 formed at the preset position in the insulating film 60 provided on the wiring 50 of the substrate (wafer W), the via 70 being extended to the wiring 70, the monomolecular film 80 on the bottom surface 73 at which the wiring 50 is exposed (process S101); forming the barrier film 81 on the side surface 72 of the via 70 (process S102); removing the monomolecular film 80 (process S103); and forming the electroless plating film 82 from the bottom surface 73 of the via 70 by using the wiring 50 exposed at the bottom surface 73 of the via 70 as the catalyst (process S104). Through these processes, the metal wiring without having the void or the seam can be effectively formed near the bottom portion of the via 70 having the high aspect ratio.

Furthermore, in the multilayer wiring forming method according to the exemplary embodiment, the monomolecular film 80 is formed with the coupling agent. Accordingly, it is possible to form the monomolecular film 80 selectively on the bottom surface 73 of the via 70.

Moreover, in the multilayer wiring forming method according to the exemplary embodiment, the electroless plating film 82 contains Cu, Co, Ni or Ru. Accordingly, it is possible to form the electroless plating film 82 efficiently from the bottom surface 73 of the via 70 by using the wiring 50 containing Cu, Co, Ni or Ru as the catalyst.

In addition, the recording medium according to the exemplary embodiment is a computer-executable and computer-readable recording medium having stored thereon computer-executable instructions for controlling the multilayer wiring forming system 1. When executed, the instructions allow the multilayer wiring forming system 1 to perform the above-described multilayer wiring forming method. Accordingly, the metal wiring without having the void or the seam can be formed effectively near the bottom portion of the via 70 having the high aspect ratio.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

### EXPLANATION OF CODES

W: Wafer

1: Multilayer wiring forming system

16: Monomolecular film forming unit

17: Film forming unit

18: Electroless plating unit

21: Controller

50: Wiring

60: Insulating film

70: Via

72: Side surface

73: Bottom surface

80: Monomolecular film

81: Barrier film

82: Electroless plating film

1. A multilayer wiring forming method, comprising:
forming, in a via formed at a preset position in an insulating film provided on a wiring of a substrate, the via being extended to the wiring, a monomolecular film on a bottom surface of the via at which the wiring is exposed;
forming a barrier film on a side surface of the via;
removing the monomolecular film; and
forming an electroless plating film from the bottom surface of the via by using the wiring exposed at the bottom surface of the via as a catalyst.

2. The multilayer wiring forming method of claim 1,
wherein the monomolecular film is formed with a coupling agent.

3. The multilayer wiring forming method of claim 1,
wherein the electroless plating film contains Cu, Co, Ni or Ru.

4. A computer-readable recording medium having stored thereon computer-executable instructions that, in response to execution, cause a multilayer wiring forming system to perform a multilayer wiring forming method as claimed in claim 1.
